(19) United States
(12) Patent Application Publication
(10) Pub. No.: US 2025/0350259 A1
(43) Pub. Date: Nov. 13, 2025

(54) TUNABLE BULK ACOUSTIC WAVE DEVICE

(71) Applicant: Skyworks Solutions, Inc., Irvine, CA (US)

(72) Inventors: Eesa Rahimi, Greensboro, NC (US); Joshua James Caron, Summerfield, NC (US)

(21) Appl. No.: 19/202,991

(22) Filed: May 8, 2025

Related U.S. Application Data
(60) Provisional application No. 63/644,986, filed on May 9, 2024.
(60) Provisional application No. 63/644,984, filed on May 9, 2024.

(51) Int. Cl. H03H 9/205; H03H 9/02; H03H 9/13; H03H 9/54

(52) U.S. Cl. CPC H03H 9/205; H03H 9/02157; H03H 9/131; H03H 9/545

(57) ABSTRACT

A bulk acoustic wave device includes a first electrode, a second electrode, a first piezoelectric layer between the first electrode and the second electrode, a third electrode, and a second piezoelectric layer. The second piezoelectric layer is between the second electrode and the third electrode.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

The disclosed technology relates to acoustic wave devices. Embodiments of this disclosure relate to acoustic wave devices with a frame structure positioned in a frame region outside of an active region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to meeting performance specifications for BAW devices while also meeting the physical size specifications.

### SUMMARY OF CERTAIN EMBODIMENTS

In some aspects, the techniques described herein relate to a bulk acoustic wave device including: a first electrode; a second electrode; a first piezoelectric layer between the first electrode and the second electrode; a third electrode; and a second piezoelectric layer between the second electrode and the third electrode.

In some aspects, the techniques described herein relate to a bulk acoustic wave device wherein the third electrode is configured to be floating in a first state and electrically connected to the second electrode in a second state.

In some aspects, the techniques described herein relate to a bulk acoustic wave device further including circuitry configured to select the first state or the second state.

In some aspects, the techniques described herein relate to a bulk acoustic wave device wherein the circuitry includes a switch, the switch connects the third electrode and the second electrode in the second state.

In some aspects, the techniques described herein relate to a method 4 includes actuating the switch to disconnect the third electrode from the second electrode in the first state and actuating the switch to connect the third electrode and the second electrode in the second state.

In some aspects, the techniques described herein relate to a bulk acoustic wave device wherein the circuitry includes a transformer electrically connected between the second electrode and the third electrode.

In some aspects, the techniques described herein relate to a bulk acoustic wave device wherein the circuitry includes a varactor electrically connected between the second electrode and the third electrode.

In some aspects, the techniques described herein relate to a bulk acoustic wave device operates in a first frequency band in the first state and in a second frequency band different from the first frequency band in the second state.

In some aspects, the techniques described herein relate to a bulk acoustic wave device wherein the first frequency band at least partially overlaps with the second frequency band.

In some aspects, the techniques described herein relate to a bulk acoustic wave device wherein the first frequency band is within the second frequency band.

In some aspects, the techniques described herein relate to a bulk acoustic wave device wherein the first frequency band is non-overlapping with the second frequency band.

In some aspects, the techniques described herein relate to a bulk acoustic wave device wherein the first piezoelectric layer is thinner than the second piezoelectric layer.

In some aspects, the techniques described herein relate to a bulk acoustic wave device further including a fourth electrode and a third piezoelectric layer between the third electrode and the fourth electrode.

In some aspects, the techniques described herein relate to a bulk acoustic wave device including: a first electrode structure including a first electrode; a second electrode structure including a second electrode and a third electrode; a first piezoelectric layer between the first electrode and the second electrode; and a second piezoelectric layer between the second electrode and the third electrode.

In some aspects, the techniques described herein relate to a bulk acoustic wave device wherein the third electrode is floating in a first state and electrically connected to the second electrode in a second state.

In some aspects, the techniques described herein relate to a bulk acoustic wave device further including circuitry including a switch, the switch connects the third electrode and the second electrode in the second state.

In some aspects, the techniques described herein relate to a bulk acoustic wave device operates in a first frequency band in the first state and in a second frequency band different from the first frequency band in the second state.

In some aspects, the techniques described herein relate to a bulk acoustic wave device further including a third piezoelectric layer, wherein the second electrode structure further includes a fourth electrode and the third piezoelectric layer is positioned between the third electrode and the fourth electrode.

In some aspects, the techniques described herein relate to an acoustic wave filter for filtering a radio frequency signal, the acoustic wave filter including: a bulk acoustic wave device of any preceding claim; and an additional acoustic wave device, the bulk acoustic wave device and the additional acoustic wave device configured to filter the radio frequency signal.

In some aspects, the techniques described herein relate to an acoustic wave filter wherein the additional acoustic wave device is a tunable bulk acoustic wave device that operates in two or more different states.

In some aspects, the techniques described herein relate to a bulk acoustic wave device including: a first resonator including a first electrode, a second electrode, and a piezoelectric structure, the piezoelectric structure having a first piezoelectric layer between the first electrode and the second electrode and a second piezoelectric layer; and a second resonator including the first electrode, the second electrode, the first piezoelectric layer between the first electrode and the second electrode, a third electrode, and the second piezoelectric layer between the second electrode and the third electrode.

In some aspects, the techniques described herein relate to a bulk acoustic wave device wherein the first resonator is active and the second resonator is inactive in a first state, and the first resonator is inactive and the second resonator is active in a second state.

In some aspects, the techniques described herein relate to a bulk acoustic wave device wherein the third electrode is floating in a first state and electrically connected to the second electrode in a second state.

In some aspects, the techniques described herein relate to a bulk acoustic wave device further including circuitry configured to select the first state or the second state.

In some aspects, the techniques described herein relate to a bulk acoustic wave device wherein the circuitry includes a switch, the switch connects the third electrode and the second electrode in the second state.

In some aspects, the techniques described herein relate to a method 5 includes switching the switch off to disconnect the third electrode from the second electrode in the first state and switching the switch on to connect the third electrode and the second electrode in the second state.

In some aspects, the techniques described herein relate to a bulk acoustic wave device wherein the circuitry includes a transformer electrically connected between the second electrode and the second electrode.

In some aspects, the techniques described herein relate to a bulk acoustic wave device wherein the circuitry includes a varactor electrically connected between the second electrode and the second electrode.

In some aspects, the techniques described herein relate to a bulk acoustic wave device wherein the first resonator has a first frequency band and the second resonator has a second frequency band different from the first frequency band.

In some aspects, the techniques described herein relate to a bulk acoustic wave device wherein the first frequency band at least partially overlaps with the second frequency band.

In some aspects, the techniques described herein relate to a bulk acoustic wave device wherein the first frequency band is within the second frequency band.

In some aspects, the techniques described herein relate to a bulk acoustic wave device wherein the first frequency band is non-overlapping with the second frequency band.

In some aspects, the techniques described herein relate to a bulk acoustic wave device wherein the first piezoelectric layer is thinner than the second piezoelectric layer.

In some aspects, the techniques described herein relate to a bulk acoustic wave device further including a third resonator including a fourth electrode and a third piezoelectric layer between the third electrode and the fourth electrode.

In some aspects, the techniques described herein relate to a bulk acoustic wave device including: a first resonator including a stack of a first electrode, a second electrode, and a piezoelectric structure; a second resonator including the stack and a third electrode; and a circuitry configured to activate the first resonator in a first state and activate the second resonator in a second state different from the first state.

In some aspects, the techniques described herein relate to a bulk acoustic wave device wherein the piezoelectric structure includes a first piezoelectric layer positioned between the first electrode and the second electrode, and a second piezoelectric layer positioned between the second electrode and the third electrode.

In some aspects, the techniques described herein relate to a bulk acoustic wave device wherein the circuitry includes a switch, the switch connects the third electrode and the second electrode in the second state.

In some aspects, the techniques described herein relate to a bulk acoustic wave device wherein the first resonator and the second resonator are positioned over a reflector.

In some aspects, the techniques described herein relate to an acoustic wave filter for filtering a radio frequency signal, the acoustic wave filter including: a bulk acoustic wave device of any preceding claim; and an additional acoustic wave device, the bulk acoustic wave device and the additional acoustic wave device configured to filter the radio frequency signal.

In some aspects, the techniques described herein relate to an acoustic wave filter wherein the additional acoustic wave device is a tunable bulk acoustic wave device that operates in two or more different states.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device according to an embodiment.

FIG. 1B is a plot showing stress distribution in the BAW device of FIG. 1A in a first state and a second state.

FIG. 2A is a stress distribution map showing stress distribution in the BAW device of FIG. 1A in the first state.

FIG. 2B is a stress distribution map showing stress distribution in the BAW device of FIG. 1A in the second state.

FIG. 2C is a graph showing normalized stress curves of the stress distributions of the BAW device of FIG. 1A in the first state and the second state.

FIG. 3 is a graph showing simulated frequency responses of the BAW device of FIG. 1A in the first state and the second state.

FIGS. 4A-4D are graphs showing simulated frequency results of the BAW device of FIG. 1A with Mason model in a first state and a second state.

FIGS. 5A-5L show simulation results of the BAW device of FIG. 1A with different electrode thicknesses.

FIGS. 6A and 6B show simulation results of the BAW device of FIG. 1A with different piezoelectric layer thicknesses.

FIGS. 7A and 7B show simulation results of the BAW device of FIG. 1A with different resistances of a switch.

FIG. 8A, 8B-2, 8C-2, 8D, and 8E show example frequency responses of the BAW device of FIG. 1A in various applications.

FIGS. 8B-1 and 8C-1 are schematic cross-sectional side views of bulk acoustic wave (BAW) devices according to various embodiments.

FIG. 9 is a schematic cross-sectional side view of a BAW device according to an embodiment.

FIG. 10 shows the BAW device as an example of a film bulk acoustic wave resonator (FBAR).

FIG. 11 shows the BAW device as an example of a BAW solidly mounted resonator (SMR).

FIG. 12A-1 is a schematic diagram of a ladder filter that includes one or more BAW resonators according to an embodiment.

FIG. 12A-2 is a schematic circuit diagram of a filter that includes one or more BAW resonators according to an embodiment.

FIG. 12B is schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Acoustic wave filters implemented in radio frequency electronic systems, such as a radio frequency front end of a mobile phone, can, for example, remove unwanted frequency components of a signal. A plurality of acoustic wave filters can be arranged as a multiplexer. Some of the filters may be designed to filter different frequency components of the signal from other filters. A radio frequency electronic system may not use all of the filters included in the system depending on the application. The plurality of acoustic wave filters can occupy a significant real-estate of the radio frequency electronic system. Also, including more filters can increase the cost per system.

Various embodiments disclosed herein relate to tunable bulk acoustic wave (BAW) devices, such as multiplexers, that operate in two or more states. For example, a BAW device according to some embodiments can include a first state in which the BAW device operates in a first band and a second state in which the BAW device operates in a second band different from the first band. The tunability can be enabled by including two or more resonators that share a piezoelectric structure. In some embodiments, the BAW device can include a first electrode, a second electrode, a first piezoelectric layer between the first electrode and the second electrode, a third electrode, and a second piezoelectric layer between the second electrode and the third electrode. The first piezoelectric layer and the second piezoelectric layer can together define a piezoelectric structure. In a first state, a first resonator that includes the first electrode, the second electrode, and the piezoelectric structure can operate. In the first state, the third electrode can be floating. In a second state, a second resonator that includes the first electrode, the second electrode, the third electrode, and the piezoelectric structure can operate. In the second state, the third electrode can be coupled to the second electrode.

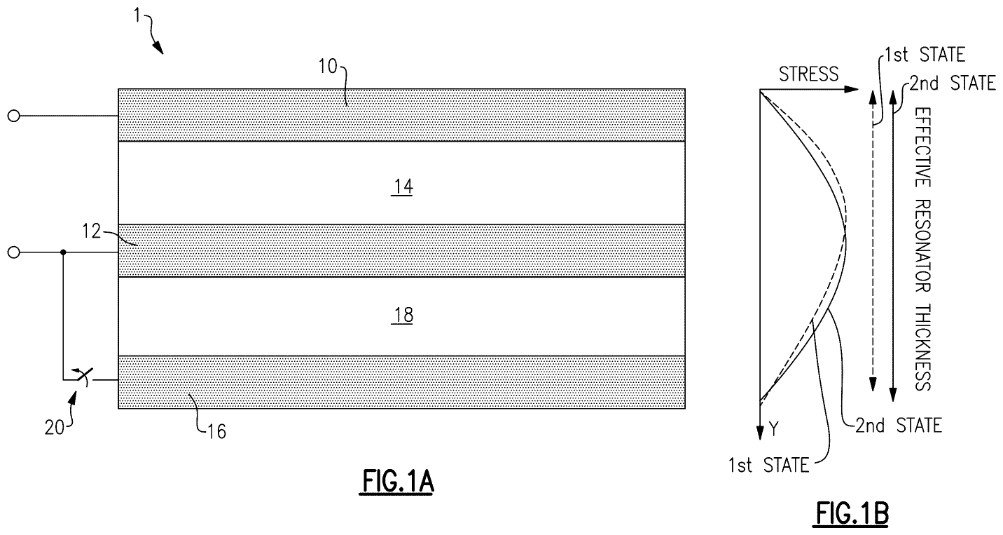

FIG. 1A is a schematic cross-sectional side view of a bulk acoustic wave (BAW) device 1 according to an embodiment. The BAW device 1 can include a first electrode 10, a second electrode 12, a first piezoelectric layer 14 between the first electrode 10 and the second electrode 12, a third electrode 16, and a second piezoelectric layer 18 between the second electrode 12 and the third electrode 16. The first piezoelectric layer 14 and the second piezoelectric layer 18 can together define a piezoelectric structure.

In some embodiments, the BAW device 1 can operate in a first state in which the BAW device 1 operates in a first band and a second state in which the BAW device operates in a second band different from the first band. The third electrode 16 can be floating in the first state and connected to the second electrode in the second state. In the first state, the first electrode 10, the second electrode 12, and the piezoelectric structure (e.g., the first and second piezoelectric layers 14, 18) can operate as a first resonator. In the first state, the stress can be concentrated between the first electrode 10 and the second electrode 12 or in the first piezoelectric layer 14. In the second state, the first electrode 10, the second electrode 12, the third electrode 16, and the piezoelectric structure (e.g., the first and second piezoelectric layers 14, 18) can operate as a second resonator.

A resonance frequency (fᵣ) of the BAW device 1 is inversely related to effective thickness (d_{effective}) of the BAW device 1. By switching between the first state and the second state, the effective thickness can be tailored, and resonance frequency can be changed. The resonance frequency can be calculated by dividing the effective velocity (v) by double the effective thickness (d_{effective}). Through changing the resonance of the BAW device 1 by switching between the first state for using the first resonator and the second state to use the second resonator, the filter response can be altered.

In some embodiments, the BAW device 1 can switch between the first state and the second state by way of circuitry that includes a switch 20. In the first state, the switch 20 can be off such that the third electrode 16 is disconnected from the second electrode 12 and floating. In the second state, the switch 20 can be on such that the third electrode 16 is connected to the second electrode 12 or to the same power source or node. In some embodiments, the first electrode 10 can be connected (e.g., permanently connected) to an output node, and the second electrode 12 can be connected (e.g., permanently connected) to an input node. In some other embodiments, there may be a switch (not shown) between the input node and the second electrode 12. In some embodiments, the BAW device 1 can include one or more electrical components in the circuitry in place or in addition to the switch 20.

The electrodes (e.g., the first electrode 10, the second electrode 12, and the third electrode 16) of the BAW device 1 can have a relatively high acoustic impedance. One or more of the electrodes of the BAW device 1 can include molybdenum (Mo), tungsten (W), ruthenium (Ru), chromium (Cr), iridium (Ir), platinum (Pt), or any suitable alloy and/or combination thereof. Two or more of the electrodes of the BAW device 1 can be formed of the same material in certain applications. The thicknesses of the electrodes of the BAW device 1 can be approximately the same in some applications. In some other applications, the thicknesses of the electrodes of the BAW device 1 can be different.

The piezoelectric layers (e.g., the first piezoelectric layer 14 and the second piezoelectric layer 18) can include a suitable material such as, but not limited to, aluminum nitride (AlN), zinc oxide (ZnO), or lead zirconium titanate (PZT). In certain applications, the piezoelectric layers 14, 18 can be an AlN layer. The piezoelectric material can be doped or undoped. For example, an AlN-based piezoelectric layer can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain applications, the piezoelectric layers 14, 18 can be AlN based layer doped with Sc. Doping the piezoelectric layers 14, 18 can adjust the resonant frequency. Doping the piezoelectric layers 14, 18 can increase the electromechanical coupling coefficient (kt²) of the BAW device 1. Doping to increase the kt² can be advantageous at higher frequencies where kt² can be degraded. In some embodiments, the piezoelectric layers 14, 18 can include the same material or different materials.

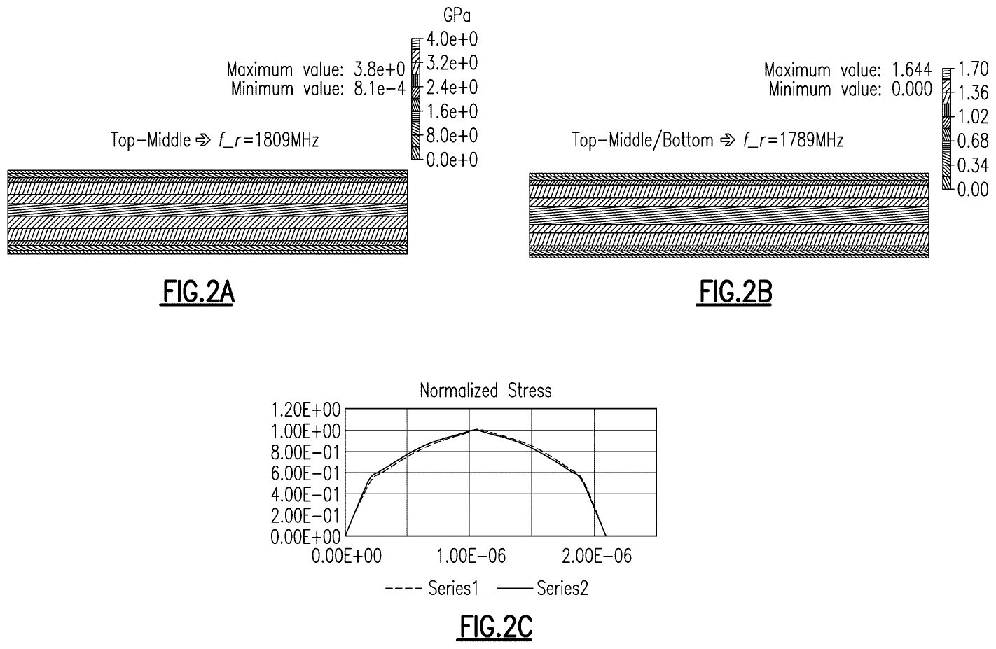

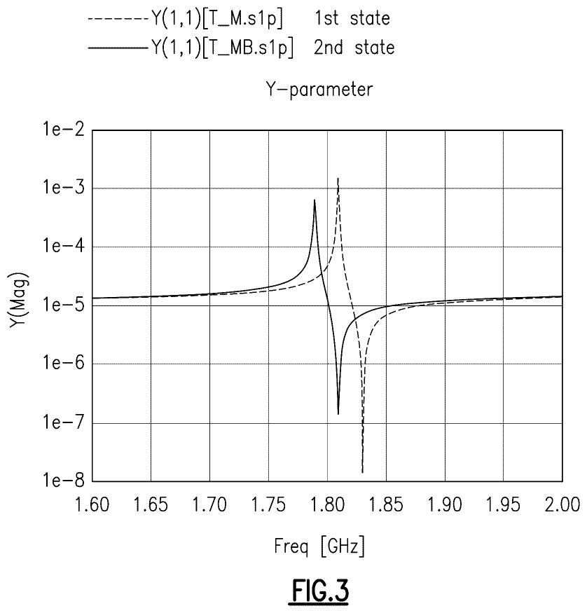

FIG. 1B is a plot that shows example stress distribution curves along the effective resonator thickness of the BAW device 1 of FIG. 1A in the first state and the second state. FIG. 1B indicates that the shapes of the filter response change between the first state and the second state. This change can be used to tune the BAW device 1 to operate in two or more bands without having two or more separate filters. FIGS. 2A-2C show more specific example of an operation of the BAW device 1.

FIG. 2A is a stress distribution map showing stress distribution in the BAW device 1 in the first state. FIG. 2B is a stress distribution map showing stress distribution in the BAW device 1 in the second state. FIG. 2C is a graph showing normalized stress curves of the stress distributions of the BAW device 1 in the first state and the second state. In the particular examples shown in FIGS. 2A-2C, the resonance frequency of the BAW device 1 in the first state is 1809 MHz and the resonance frequency of the BAW device 1 in the second state is 1789 MHz. The stress patterns of the stress distribution are changed between the first state and the second state, and the maximum stress location of the second state is shifted up closer to the first electrode 10 as compared to the first state.

FIG. 3 is a graph showing simulated frequency responses of the BAW device 1 in the first state and the second state. FIG. 3 indicates that the admittance is greater in the first state than the second state. In the simulations, it is assumed that the switch 20 has an ideal performance (e.g., no current loss through the switch).

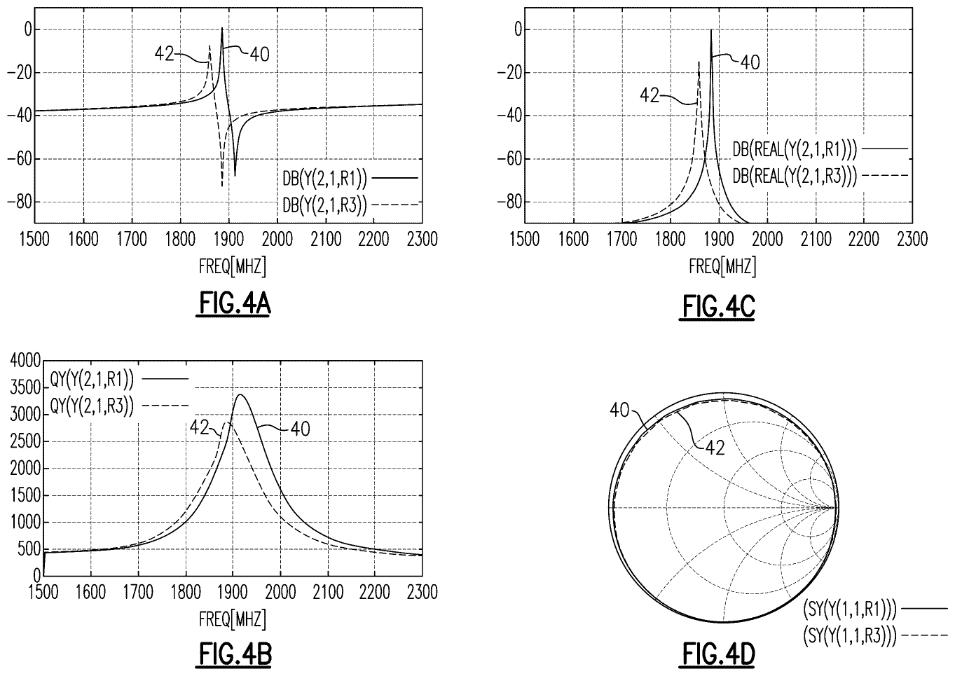

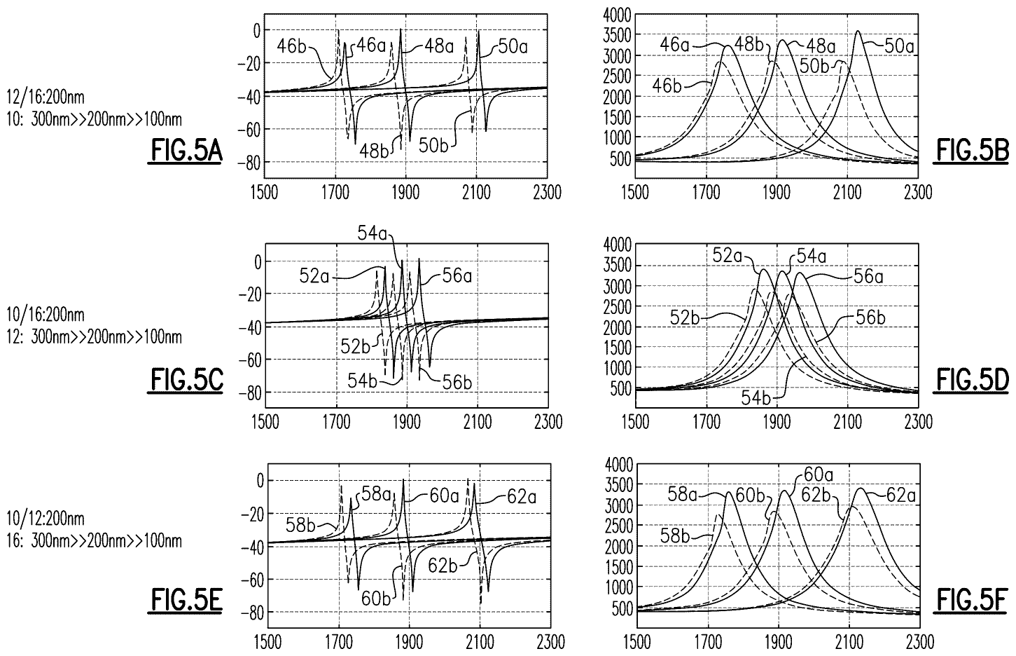

FIGS. 4A-4D are graphs showing simulated frequency results of the BAW device 1 with Mason model in a first state 40 and a second state 42. FIGS. 4A-4D indicate that the BAW device 1 can enable tunability between the first state 40 and the second state 42 while maintaining a relatively high quality factor (Q).

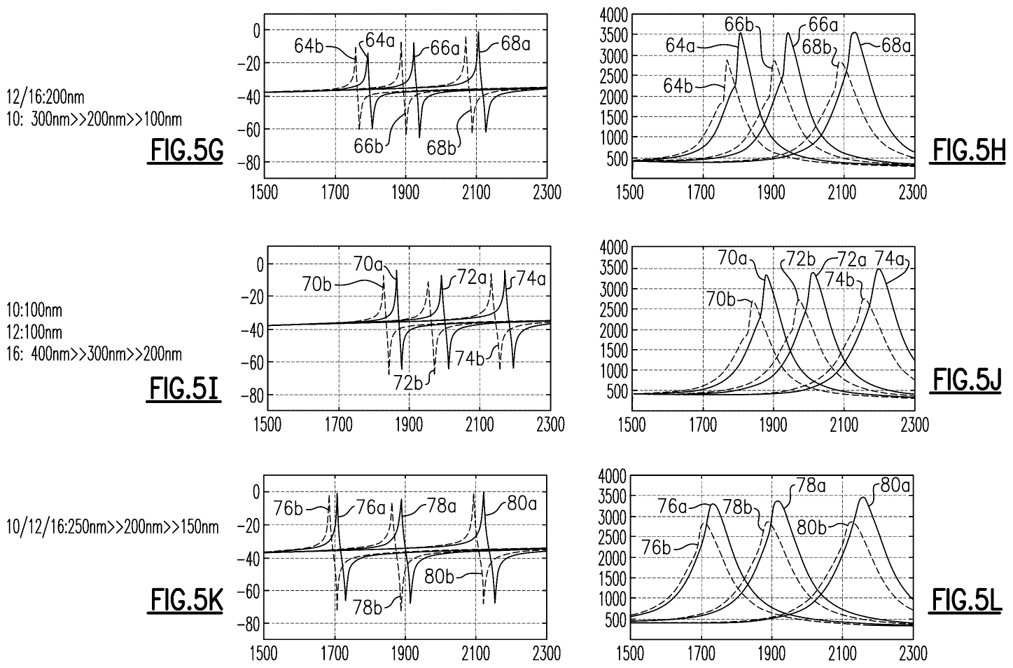

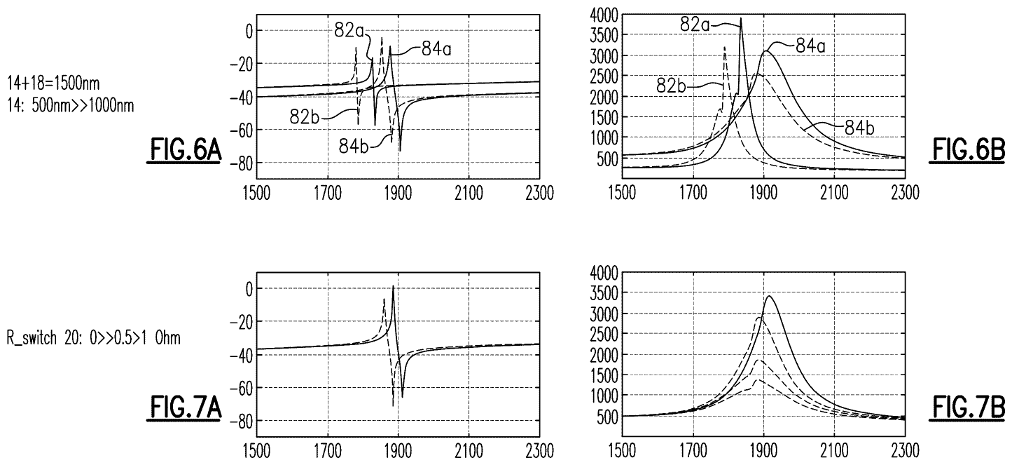

Various parameters of the BAW device 1 can be optimized to provide desired performance (e.g., the resonance frequency, the coupling coefficient, and/or the quality factor). For example, the thicknesses of the piezoelectric layers 14, 18, and the electrodes 10, 12, 16 can contribute to the device performance. The quality of the switch 20 can also affect the performance of the BAW device 1. FIGS. 5A-5L show simulation results of the BAW device 1 with different electrode thicknesses. FIGS. 6A and 6B show simulation results of the BAW device 1 with different piezoelectric layer thicknesses. FIGS. 7A and 7B show simulation results of the BAW device 1 with different resistances of the switch 20.

In the simulations of FIGS. 5A and 5B, the thicknesses of the second and third electrodes 12, 16 are set to 200 nanometers, and the thickness of the first electrode 10 is set to 300 nanometers, 200 nanometers, and 100 nanometers. FIGS. 5A and 5B show simulation results 46a (the first electrode 10 at 300 nanometers in the first state), 46b (the first electrode 10 at 300 nanometers in the second state), 48a (the first electrode 10 at 200 nanometers in the first state), 48b (the first electrode 10 at 200 nanometers in the second state), 50a (the first electrode 10 at 100 nanometers in the first state), and 50b (the first electrode 10 at 100 nanometers in the second state).

In the simulations of FIGS. 5C and 5D, the thicknesses of the first and third electrodes 10, 16 are set to 200 nanometers, and the thickness of the second electrode 12 is set to 300 nanometers, 200 nanometers, and 100 nanometers. FIGS. 5C and 5D show simulation results 52a (the second electrode 12 at 300 nanometers in the first state), 52b (the second electrode 12 at 300 nanometers in the second state), 54a (the second electrode 12 at 200 nanometers in the first state), 54b (the second electrode 12 at 200 nanometers in the second state), 56a (the second electrode 12 at 100 nanometers in the first state), and 56b (the second electrode 12 at 100 nanometers in the second state).

In the simulations of FIGS. 5E and 5F, the thicknesses of the first and second electrodes 10, 12 are set to 200 nanometers, and the thickness of the third electrode 16 is set to 300 nanometers, 200 nanometers, and 100 nanometers. FIGS. 5E and 5F show simulation results 58a (the third electrode 16 at 300 nanometers in the first state), 58b (the third electrode 16 at 300 nanometers in the second state), 60a (the third electrode 16 at 200 nanometers in the first state), 60b (the third electrode 16 at 200 nanometers in the second state), 62a (the third electrode 16 at 100 nanometers in the first state), and 62b (the third electrode 16 at 100 nanometers in the second state).

In the simulations of FIGS. 5G and 5H, the thickness of the first electrode 10 is set to 100 nanometers, the thickness the second electrode 12 is set to 200 nanometers, and the thickness of the third electrode 16 is set to 400 nanometers, 300 nanometers, and 200 nanometers. FIGS. 5G and 5H show simulation results 64a (the third electrode 16 at 400 nanometers in the first state), 64b (the third electrode 16 at 400 nanometers in the second state), 66a (the third electrode 16 at 300 nanometers in the first state), 66b (the third electrode 16 at 300 nanometers in the second state), 68a (the third electrode 16 at 200 nanometers in the first state), and 68b (the third electrode 16 at 200 nanometers in the second state).

In the simulations of FIGS. 5I and 5J, the thicknesses of the first and second electrodes 10, 12 are set to 100 nanometers, and the thickness of the third electrode 16 is set to 400 nanometers, 300 nanometers, and 200 nanometers. FIGS. 5I and 5J show simulation results 70a (the third electrode 16 at 400 nanometers in the first state), 70b (the third electrode 16 at 400 nanometers in the second state), 72a (the third electrode 16 at 300 nanometers in the first state), 72b (the third electrode 16 at 300 nanometers in the second state), 74a (the third electrode 16 at 200 nanometers in the first state), and 74b (the third electrode 16 at 200 nanometers in the second state).

In the simulations of FIGS. 5K and 5L, the thickness of the first electrode 10 is set to 250 nanometers, 200 nanometers, and 150 nanometers, the thickness the second electrode 12 is set to 250 nanometers, 200 nanometers, and 150 nanometers, and the thickness of the third electrode 16 is set to 250 nanometers, 200 nanometers, and 150 nanometers. FIGS. 5K and 5L show simulation results 76a (the first to third electrodes 10, 12, 16 at 250 nanometers in the first state), 76b (the first to third electrodes 10, 12, 16 at 250 nanometers in the second state), 78a (the first to third electrodes 10, 12, 16 at 200 nanometers in the first state), 78b (the first to third electrodes 10, 12, 16 at 200 nanometers in the second state), 80a (the first to third electrodes 10, 12, 16 at 150 nanometers in the first state), and 80b (the first to third electrodes 10, 12, 16 at 150 nanometers in the second state).

The simulation results of FIGS. 5A-5L indicate that the frequency and the quality factor can be higher when the thicknesses of the first electrode 10, the second electrode 12, and/or the third electrode 16 are thinner. Compared to the results of FIGS. 5A and 5B, the changes in the resonance frequencies due to the change in the thickness of the second electrode 12 are smaller than when the first electrode 10 is changed. Also, the frequency shift between the first state and the second state becomes larger when the thickness of the first electrode 10 is thinner. Further, although the quality factor of the first state is greater than the second state, the quality factor of the second state is still maintained at a relatively high level.

In the simulations of FIGS. 6A and 6B, the aluminum nitride (AlN) piezoelectric layers were used as the first and second piezoelectric layers 14, 18 of the BAW device 1. The total thickness of the first and second piezoelectric layers 14, 18 is set to 1500 nanometers, and the thickness of the first piezoelectric layer 14 was set to 500 nanometers and 1000 nanometers. FIGS. 6A and 6B show simulation results 82a (the first piezoelectric layer 14 at 500 nanometers in the first state), 82b (the first piezoelectric layer 14 at 500 nanometers in the second state), 84a (the first piezoelectric layer 14 at 1000 nanometers in the first state), and 84b (the first piezoelectric layer 14 at 1000 nanometers in the second state). The simulation results of FIGS. 6A and 6B indicate that the thicknesses of the first and second piezoelectric layers 14, 18 can impact the resonance frequency and the quality factor. In some embodiments, the quality factor can be greater when the first piezoelectric layer 14 is equal to or thinner than a thickness of the second piezoelectric layer 18.

In the simulations of FIGS. 7A and 7B, the resistance of the switch 20 of the BAW device 1 is set to 0 Ohm, 0.5 Ohm, and 1 Ohm. FIGS. 7A and 7B indicate that the quality of the switch can significantly affect the quality factor of the BAW device 1.

FIGS. 5A-7B demonstrate how the thicknesses of the piezoelectric layers 14, 18, and the electrodes 10, 12, 16 and the resistance of the switch 20 can contribute to the performance of the BAW device 1. By adjusting the parameters of the BAW device 1, an optimized tunable filter can be provided. For example, the BAW device 1 can be configured to operate in two or more bands that at least partially overlap with one another, or in two or more separate bands that do not overlap with one another. In certain applications, a plurality of filters are includes in a radio frequency (RF) system for different frequency bands. Any suitable principle and advantages disclosed herein can reduce the number of the filters included in the RF system. For example, two or mode filters can be combined in a single tunable filter in accordance with suitable principle and advantages disclosed herein. When there are a plurality of filters included in the RF system, the insertion loss can grow and may negatively affect the filter performance of the RF system. Accordingly, the tunable filters (e.g., the BAW device 1) disclosed herein can reduce the size of the RF system while also reducing the insertion loss.

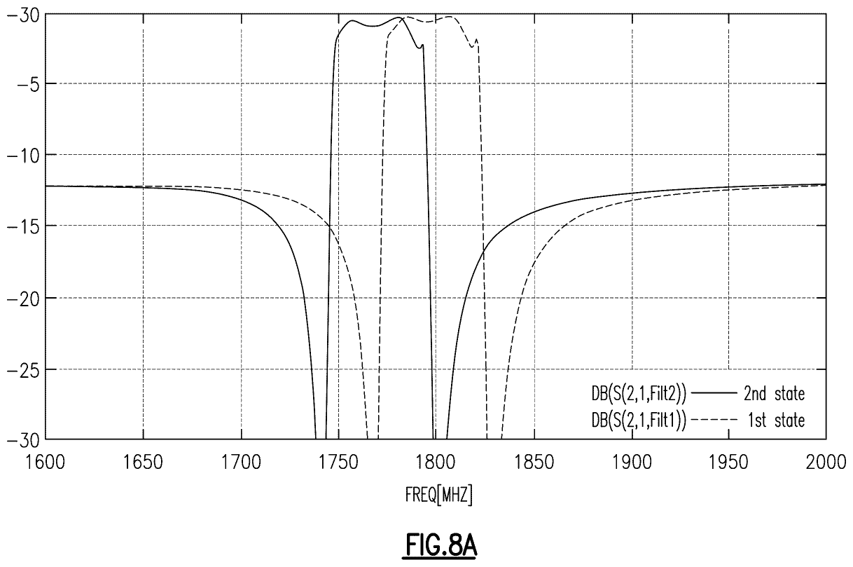

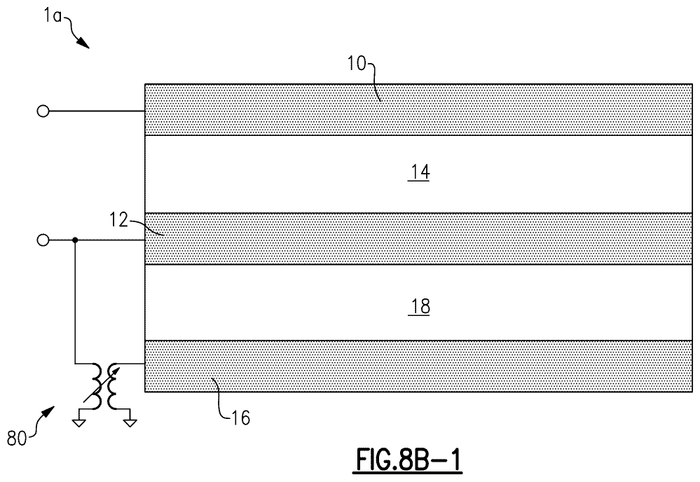

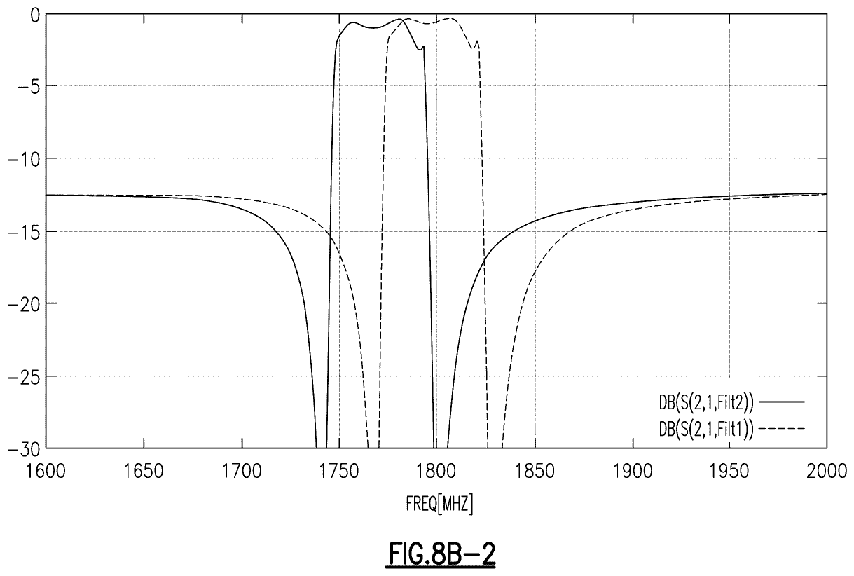

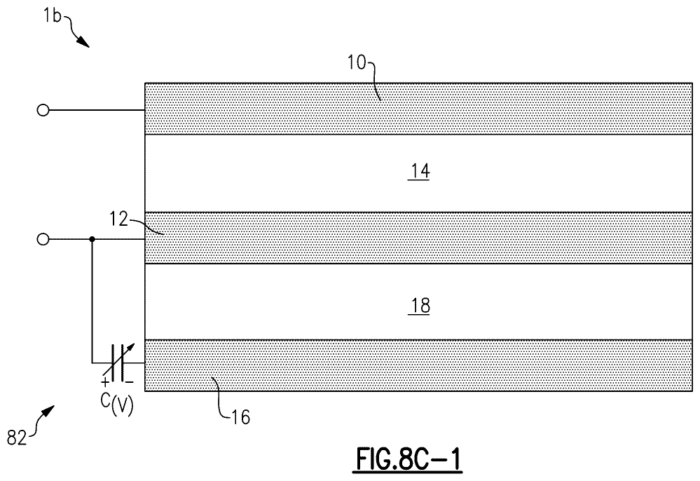

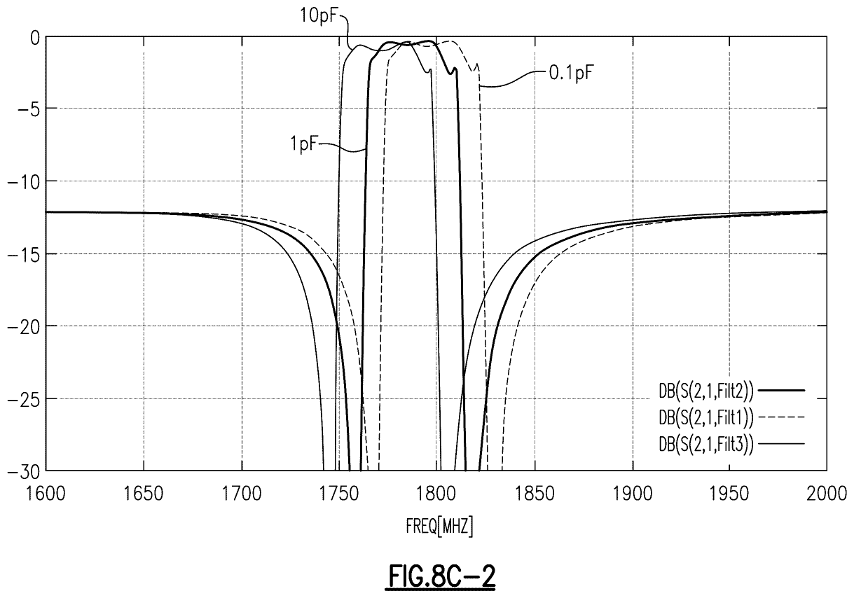

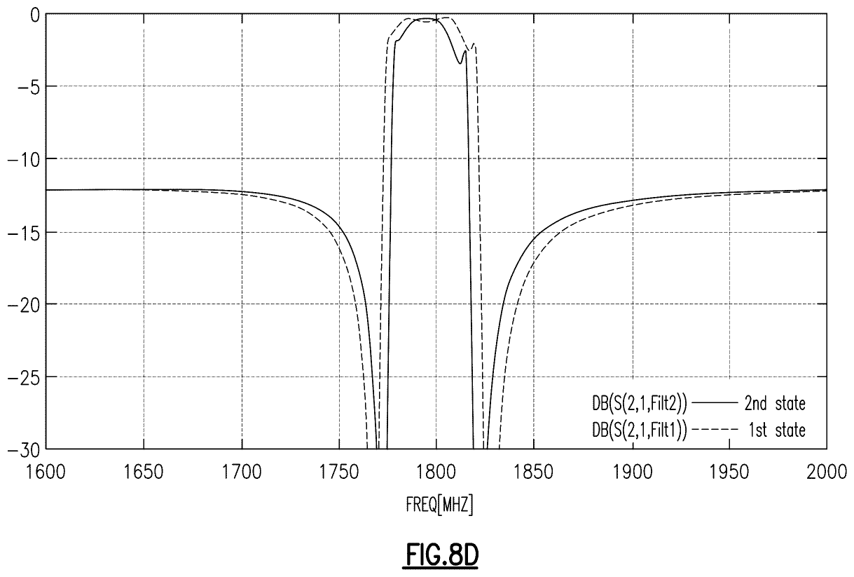

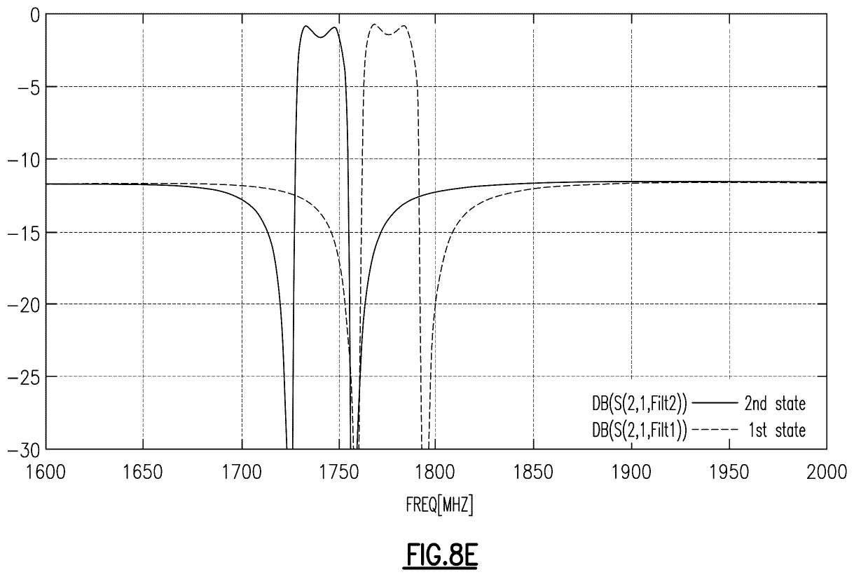

FIG. 8A shows example frequency responses of the BAW device 1 designed to operate in two bands that are partially overlapped in the first and second states of the BAW device 1. The BAW device 1 used in the simulation of FIG. 8A can represent a ladder filter with two stages. An ideal switch is used as the switch 20 and Mason model is used in the simulation. The pass band shapes of the first state and the second state remain generally similar without a significant difference.

FIG. 8B-1 is a schematic cross-sectional side view of a tunable bulk acoustic wave (BAW) device 1a according to an embodiment. Unless otherwise noted, the components of the BAW device 1a shown in FIG. 8B-1 may be structurally and/or functionally the same as or generally similar to like components of other BAW devices disclosed herein. FIG. 8B-2 shows example frequency responses of the tunable BAW device 1a designed to operate in two bands that are partially overlapped in the first and second states of the BAW device. The BAW device 1a used in the simulation of FIG. 8B-2 can be generally similar to the BAW device 1 except the switch 20 is replaced with a transformer 80. In some embodiments, the transformer 80 can be a tunable transformer. The tunable transformer can be beneficial for providing analog controllability over the frequency shift. An ideal transformer which assumes no loss is used in the simulation. FIG. 8B-2 indicates that the transformer 80 can potentially lower the loss as compared to implementing a switch 20 to switch between the first state and the second state.

FIG. 8C-1 is a schematic cross-sectional side view of a tunable bulk acoustic wave (BAW) device 1b according to an embodiment. Unless otherwise noted, the components of the BAW device 1b shown in FIG. 8C-1 may be structurally and/or functionally the same as or generally similar to like components of other BAW devices disclosed herein. FIG. 8C-2 shows example frequency responses of the tunable BAW device 1b with a varactor 82. The BAW device used in the simulation of FIG. 8C-2 can be generally similar to the BAW device 1 except the switch 20 is replaced with the varactor 82. The voltage across the varactor 82 can provide analog control over the frequency shift. The capacitance of the varactor is set at 0.1 picofarad (pF), 1 pF, and 10 pF. The simulation results of FIG. 8C-2 demonstrate that more capacitance can lower the frequency band in the tunable BAW device 1b. In some embodiments, a tunable varactor can be implemented as the varactor 82 to have more than two states in the BAW device 1b.

FIG. 8D shows example frequency responses of the BAW device 1 designed to operate in two different bandwidth in the first and second states of the BAW device 1. Therefore, the BAW device 1 can provide, for example, an improved isolation and rejection, and/or improved selectivity. In some embodiments, when a series resonator is switched from a first state to a second state, a shunt resonator can be switched from the second state to the first state.

FIG. 8E shows example frequency responses of the BAW device 1 designed to operate in two bands that are not overlapped in the first and second states of the BAW device 1. FIG. 8E demonstrates the potential of combining two or more filters having different bands (e.g., non-overlapping bands) in a single filter.

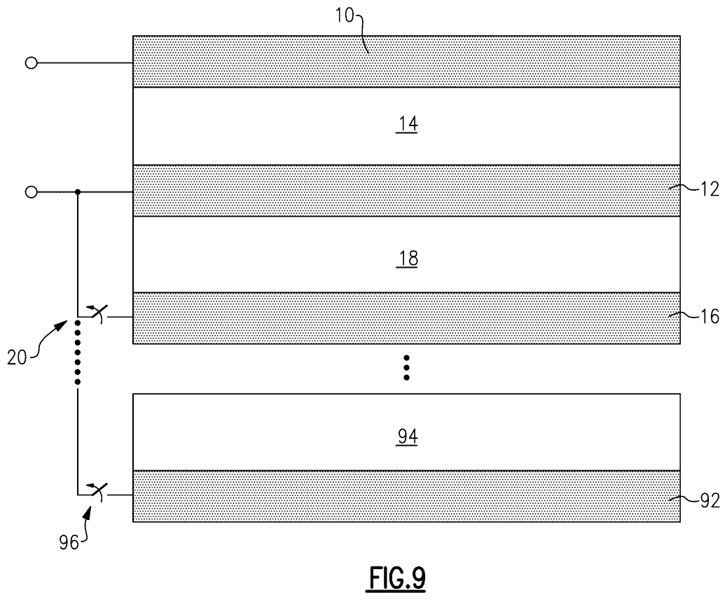

FIG. 9 is a schematic cross-sectional side view of a BAW device 2 according to an embodiment. Unless otherwise noted, the components of the BAW device 2 shown in FIG. 9 may be structurally and/or functionally the same as or generally similar to like components of other BAW devices disclosed herein. Although the BAW device 1 of FIG. 1A shows the two-state structure as an example, a single tunable BAW device (e.g., the BAW device 2) can include any suitable number of electrodes and piezoelectric layers to operate in more than two states. For example, the BAW device 2 can include an Nth electrode 92 and an Mth piezoelectric layer 94 where N is an integer greater than three and M is an integer greater than two.

In some embodiments, the Nth electrode 92 can be a fourth electrode and the Mth piezoelectric layer 94 can be a third piezoelectric layer. In such embodiments, the BAW device 2 can operate in three or more states. In some embodiments, the BAW device 2 can switch between a first state, a second state, and a third state by way of circuitry that includes switches 20, 96. In the first state, the third electrode 16 and the fourth electrode (e.g., the Nth electrode 92) can be floating. In the second state, the third electrode 16 can be connected to the second electrode 14 and the Nth electrode 92 can be floating. In the third state, the third electrode and the Nth electrode 92 can be connected to the second electrode 14. In the first state, the

The BAW devices disclosed herein can include a support substrate that supports the stacked resonators and a reflector between the support substrate and the stacked resonators. A BAW device with an air cavity can be referred to as a film bulk acoustic wave resonator (FBAR). A BAW device with a solid acoustic mirror can be referred to as a BAW solidly mounted resonator (SMR).

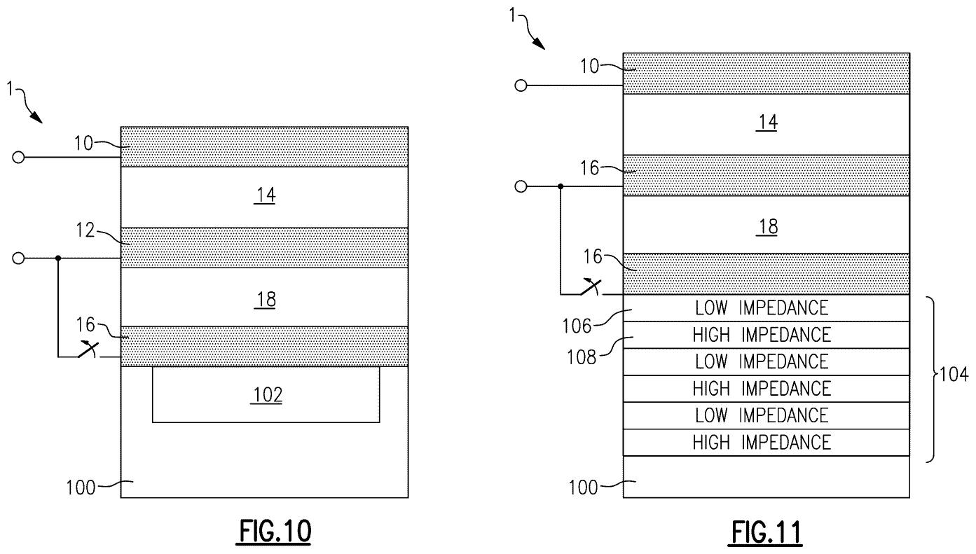

FIG. 10 shows the BAW device 1 as an example of a film bulk acoustic wave resonator (FBAR). FIG. 11 shows the BAW device 1 as an example of a BAW solidly mounted resonator (SMR). The first to third electrodes 10, 12, 16 and the piezoelectric structure (the first piezoelectric layer 14 and the second piezoelectric layer 18) are supported by a support substrate 100. In FIG. 10, there can be a cavity 102 between the support substrate 100 and the third electrode 16. In FIG. 11, there can be a solid acoustic mirror 104 between the support substrate 100 and the third electrode 16. The cavity 102 and the solid acoustic mirror 104 are examples of a reflector. A first resonator defined by the first electrode 10, the second electrode 12, and the piezoelectric structure, and a second resonator defined by the first electrode 10, the second electrode 12, the third electrode 16, and the piezoelectric structure can share the same reflector.

The support substrate 100 can be a semiconductor substrate. The support substrate 100 can be a silicon substrate. The support substrate 100 can be any other suitable support substrate, such as a substrate of quartz, silicon carbide, sapphire, glass, gallium arsenide, or any suitable ceramic (e.g., spinel, alumina, etc.). The support substrate 100 can be part of a support structure that includes, for example, the support substrate 100, a trap rich layer (not shown), a passivation layer (not shown), or one or more intermediate layers therebetween (not shown).

The illustrated solid acoustic mirror 104 includes acoustic Bragg reflectors. The illustrated acoustic Bragg reflectors can include alternating low impedance layers 106 and high impedance layers 108. As an example, the Bragg reflectors can include alternating silicon dioxide layers as low impedance layers 106 and tungsten layers as high impedance layers 108. Any other suitable features of an SMR can alternatively or additionally be implemented. Any other suitable features of BAW devices disclosed herein can be implemented in a BAW SMR.

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. Example filter topologies will be discussed with reference to FIGS. 12A-1 and 12A-2.

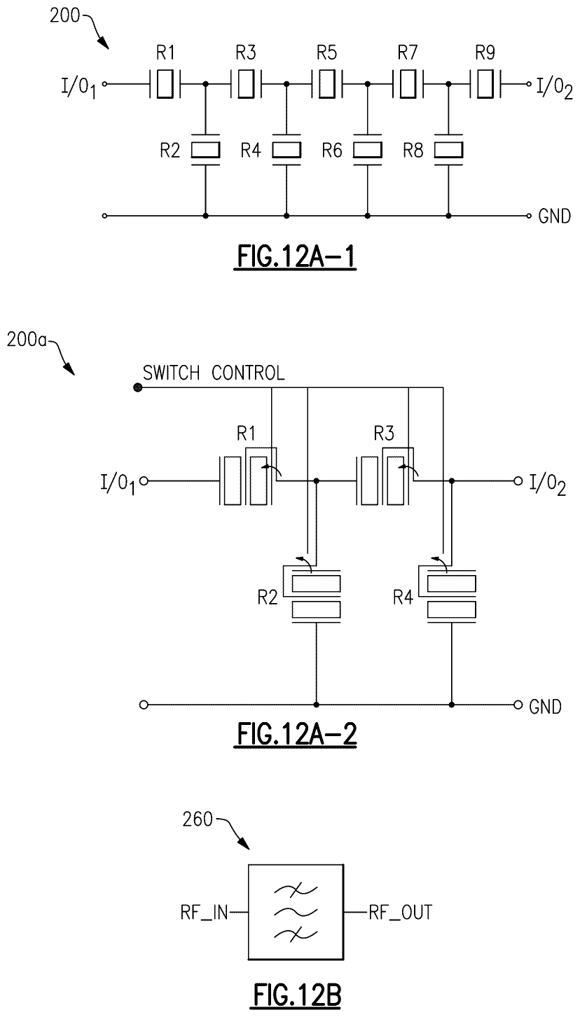

FIG. 12A-1 is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. In some embodiments, all acoustic resonators of the ladder filter 200 can include a BAW resonator in accordance with any suitable principles and advantages disclosed herein. In some other embodiments, one or more of the resonators R1-R9 may have a stack with multiple switch control inputs like FIG. 9, and/or one or more of the resonators R1-R9 may be standard resonators without a stack. For example, one or more of the resonators R1-R9 may include a switch, transformer, or a varactor. An example illustration of a filter that includes switches is shown in FIG. 12A-2.

FIG. 12A-2 is a schematic circuit diagram of a filter 200a that includes an acoustic wave resonator according to an embodiment. In some embodiments, each of the resonators R1-R4 can include a switch. The switches can be controlled by a switch controller.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

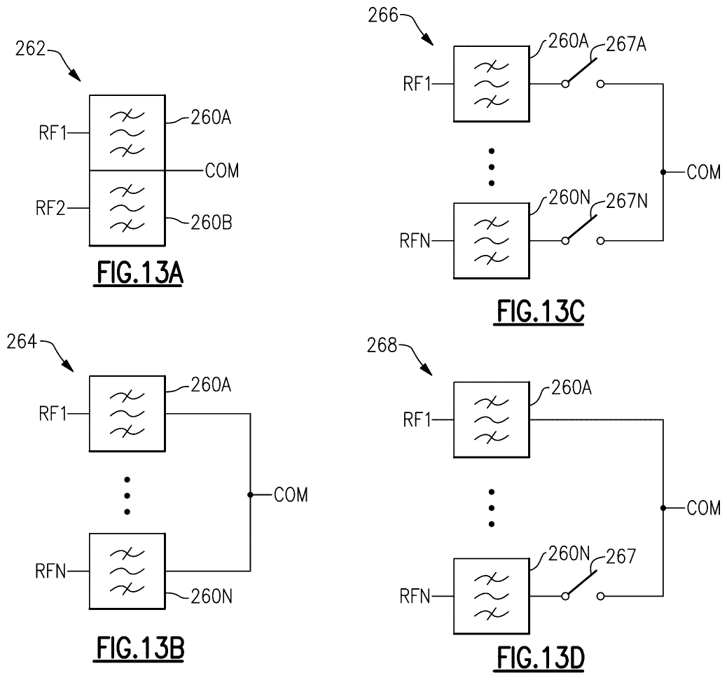

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

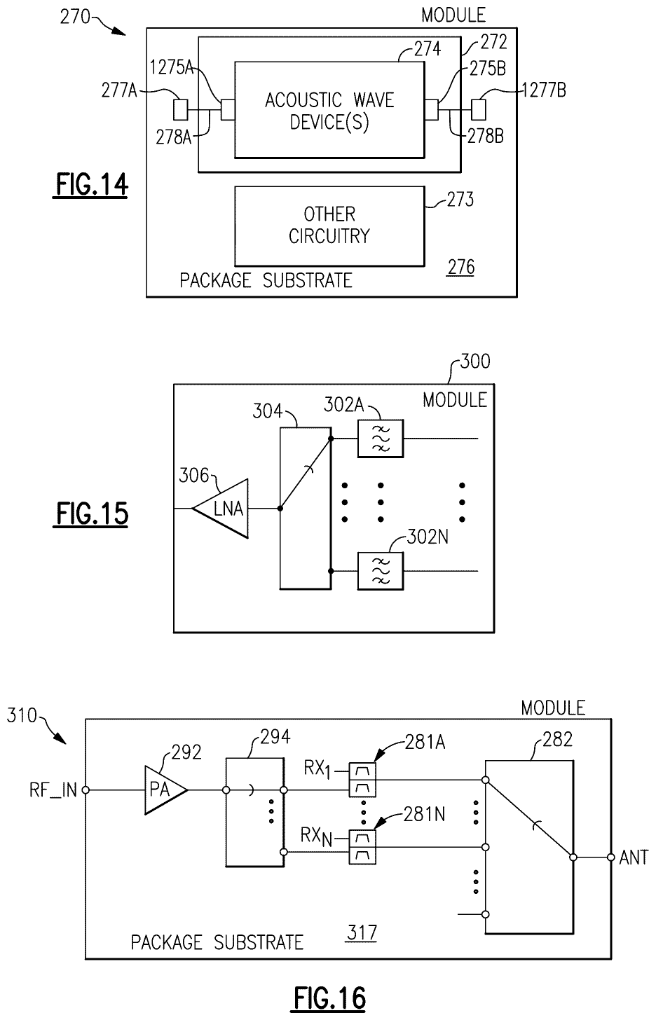

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

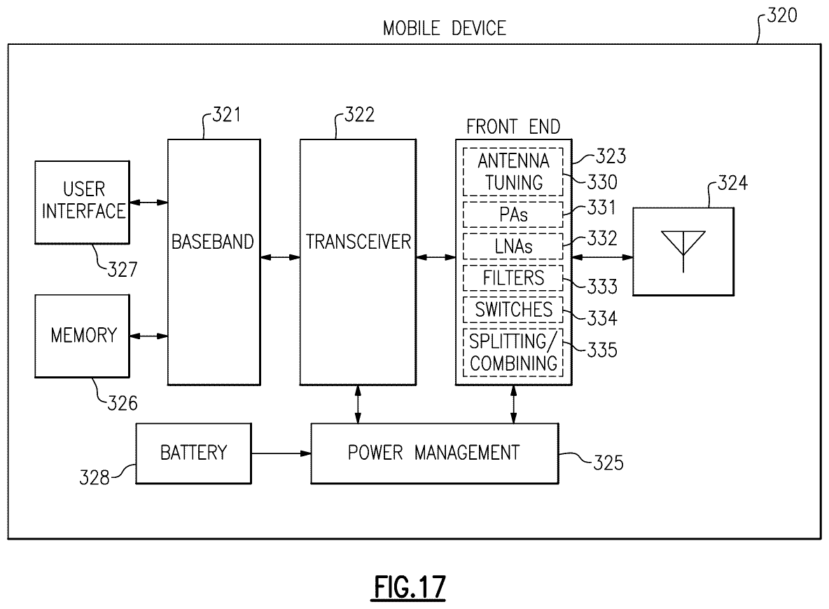

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first electrode;
a second electrode;
a first piezoelectric layer between the first electrode and the second electrode;
a third electrode; and
a second piezoelectric layer between the second electrode and the third electrode, the third electrode configured to be floating in a first state and electrically connected to the second electrode in a second state.

2. The bulk acoustic wave device of claim 1 further comprising circuitry configured to select the first state or the second state.

3. The bulk acoustic wave device of claim 2 wherein the circuitry includes a switch, the switch connects the third electrode and the second electrode in the second state.

4. A method of tuning the bulk acoustic wave device of claim 3 includes actuating the switch to disconnect the third electrode from the second electrode in the first state and actuating the switch to connect the third electrode and the second electrode in the second state.

5. The bulk acoustic wave device of claim 2 wherein the circuitry includes a transformer electrically connected between the second electrode and the third electrode.

6. The bulk acoustic wave device of claim 2 wherein the circuitry includes a varactor electrically connected between the second electrode and the third electrode.

7. The bulk acoustic wave device of claim 1 operates in a first frequency band in the first state and in a second frequency band different from the first frequency band in the second state.

8. The bulk acoustic wave device of claim 7 wherein the first frequency band at least partially overlaps with the second frequency band.

9. The bulk acoustic wave device of claim 1 wherein the first piezoelectric layer is thinner than the second piezoelectric layer.

10. The bulk acoustic wave device of claim 1 further comprising a fourth electrode and a third piezoelectric layer between the third electrode and the fourth electrode.

11. A bulk acoustic wave device comprising:
a first resonator including a first electrode, a second electrode, and a piezoelectric structure, the piezoelectric structure having a first piezoelectric layer between the first electrode and the second electrode and a second piezoelectric layer; and
a second resonator including the first electrode, the second electrode, the first piezoelectric layer between the first electrode and the second electrode, a third electrode, and the second piezoelectric layer between the second electrode and the third electrode.

12. The bulk acoustic wave device of claim 11 wherein the first resonator is active and the second resonator is inactive in a first state, and the first resonator is inactive and the second resonator is active in a second state.

13. The bulk acoustic wave device of claim 12 wherein the third electrode is floating in a first state and electrically connected to the second electrode in a second state, and the bulk acoustic wave device further comprising circuitry configured to select the first state or the second state.

14. The bulk acoustic wave device of claim 13 wherein the circuitry includes a switch, the switch connects the third electrode and the second electrode in the second state.

15. The bulk acoustic wave device of claim 13 wherein the circuitry includes at least one of a transformer and a varactor electrically connected between the second electrode and the second electrode.

16. The bulk acoustic wave device of claim 11 wherein the first resonator has a first frequency band and the second resonator has a second frequency band different from the first frequency band.

17. The bulk acoustic wave device of claim 11 wherein the first piezoelectric layer is thinner than the second piezoelectric layer.

18. The bulk acoustic wave device of claim 11 further comprising a third resonator including a fourth electrode and a third piezoelectric layer between the third electrode and the fourth electrode.

19. A bulk acoustic wave device comprising:
a first resonator including a stack of a first electrode, a second electrode, and a piezoelectric structure;
a second resonator including the stack and a third electrode; and
a circuitry configured to activate the first resonator in a first state and activate the second resonator in a second state different from the first state, the piezoelectric structure including a first piezoelectric layer positioned between the first electrode and the second electrode, and a second piezoelectric layer positioned between the second electrode and the third electrode.

20. The bulk acoustic wave device of claim 19 wherein the first resonator and the second resonator are positioned over a reflector.
